(19) United States
(12) Patent Application Publication
(10) Pub. No.: US 2017/0213648 A1
(43) Pub. Date: Jul. 27, 2017

(54) SELF-SUPPORTED ELECTRONIC DEVICES

(71) Applicant: WESTEM MICHIGAN UNIVERSITY RESEARCH FOUNDATION, Kalamazoo, MI (US)

(72) Inventors: Margaret K. JOYCE, Kalamazoo, MI (US); Michael James JOYCE, Kalamazoo, MI (US); Ali ESHKEITI, Lansing, MI (US); Massood Zandi ATASHBAR, Portage, MI (US); Paul D. FLEMING, III, Kalamazoo, MI (US)

(73) Assignee: Western Michigan University Research Foundation, Kalamazoo, MI (US)

(21) Appl. No.: 15/329,151

(22) PCT Filed: Jul. 31, 2015
(86) PCT No.: PCT/US2015/043076

§ 371 Date: Jan. 25, 2017

Related U.S. Application Data
(60) Provisional application No. 62/032,024, filed on Aug. 1, 2014.

(51) Int. Cl. H01G 4/30; H01G 11/86; H01G 11/22; H01L 21/683; B41M 5/00; B41M 1/22; H01Q 1/38; H01Q 1/22; H01F 27/28; H01G 4/32

(52) U.S. Cl. CPC H01G 4/30; H01F 27/2804; H01G 11/86; H01G 11/22; H01G 4/32; B41M 5/0023; B41M 1/22; H01Q 1/38; H01Q 1/2225; H01L 21/6835; H01Q 1/273

(57) ABSTRACT

A method of forming a self-supported electronic device, including depositing a sacrificial layer on a first surface substrate, wherein the sacrificial layer is substantially soluble in a first solvent. At least one device layer is deposited in a desired pattern on top of the sacrificial layer. The at least one device layer is substantially insoluble in the at least one device layer. The sacrificial layer is at least partially dissolved in the first solvent to release at least a portion of the first device layer from the substrate. The at least one device layer removed from the substrate forms a self-supported electronic device, which is a thin film electronic device having at least a portion thereof that is not supported by a material carrier.

### CROSS-REFERENCE TO RELATED APPLICATIONS

This application is a National Stage Application under 35 U.S.C. §371 of PCT Application No. PCT/US2015/043076, filed on Jul. 31, 2015, which claims priority under 35 U.S.C. §119(e) to U.S. Provisional Patent Application No. 62/032,024, filed on Aug. 1, 2014, entitled “SELF-SUPPORTED ELECTRONIC DEVICES,” the entire disclosures of which are hereby incorporated herein by reference.

### BACKGROUND

The present disclosure relates to self-supported electronic devices, and methods for manufacturing the same.

### SUMMARY

One aspect of the present disclosure is a self-supported electronic device, including a thin film electronic device, wherein at least a portion of the electronic device is not supported by a material carrier.

In another aspect, the present disclosure includes an assembly for producing a self-supported electronic device, including a substrate and a sacrificial layer disposed on a top surface of the substrate, wherein the sacrificial layer is soluble in a first solvent. At least one device layer is disposed on a top surface of the sacrificial layer. The at least one device layer has a thickness greater than about 10 nm and is substantially insoluble in the first solvent. The sacrificial layer is substantially insoluble in the at least one device layer.

In yet another aspect, the present disclosure includes a method of forming a self-supported electronic device, including depositing a sacrificial layer on a first surface of a substrate, wherein the sacrificial layer is substantially soluble in a first solvent. At least one device layer is deposited in a desired pattern on a top surface of the sacrificial layer, and the sacrificial layer is substantially insoluble in the at least one device layer. The sacrificial layer is at least partially dissolved in the first solvent to release at least a portion of the first device layer from the substrate.

Self-supported electronic devices, as described herein, are especially suitable for applications where a carrier substrate is undesired due to increased material costs, increased thickness, reduced flexibility, reduced conformability or incompatibility with a surface that the electronic device will be placed in contact with. The method of manufacturing the self-supported electronic devices allows formation of the self-supported electronic devices on a substrate, and the subsequent removal of the device from the substrate, which means that the substrate can be re-used for production of multiple self-supported electronic devices. Additionally, removal of the substrate allows processing of the self-supported electronic devices at higher temperatures once removed from the substrate, or prior to removal (up to the degradation temperature of the sacrificial layer), and allows the use of substrate materials that are not compatible with the final product or even the materials of the self-supported electronic device.

Another aspect of the present invention is a stretchable and wearable printed sensor for human body motion monitoring. The sensor may comprise a strain sensor that is fabricated by screen printing carbon nanotube (CNT) ink on a water-soluble polymer-based polyvinyl alcohol (PVA) substrate. The printed sensor may be transferred onto the forearm of a human, and water may be used to dissolve the sacrificial PVA layer. The sensor may be subjected to flexion and extension movements of the elbow, and the sensor may be utilized to monitor body movement. In one example, the average resistance of the sensor increased by approximately 10% for multiple flexion movements. In addition, for extension movements, a 2% increase was observed in the base resistance after 10 cycles.

These and other features, advantages, and objects of the present device will be further understood and appreciated by those skilled in the art upon studying the following specification, claims, and appended drawings.

### BRIEF DESCRIPTION OF THE DRAWINGS

FIG. 1 is a side elevation schematic view of one embodiment of an assembly of a substrate, a sacrificial layer, and a self-supported electronic device;

FIG. 2 is a side elevation schematic view of one embodiment of a self-supported electronic device;

FIG. 3 is a top view of one embodiment of a self-supported inductance coil;

FIG. 4 is a top view of one embodiment of a self-supported RFID antenna;

FIG. 5 is a top view of one embodiment of a self-supported heavy metal ion sensor;

FIG. 6 is a top exploded view of one embodiment of a self-supported capacitor;

FIG. 7 is a top view of the embodiment of the self-supported capacitor shown in FIG. 6;

FIG. 8 is a top exploded view of one embodiment of a supercapacitor;

FIG. 9 is a top view of the supercapacitor shown in FIG. 8;

FIG. 10 is a side elevation view of one embodiment of a rolled supercapacitor.

FIG. 11 is a top perspective view of one embodiment of a self-supported capacitive pressure sensor;

FIG. 12 is a side elevation view of one embodiment of a cantilevered sensor as formed on a substrate;

FIG. 13 is a schematic view of a stretchable and wearable sensor for monitoring human body motion according to another aspect of the present invention;

FIG. 14 shows the sensor of FIG. 13 printed on a sacrificial substrate prior to mounting the sensor on the skin of a human subject;

FIG. 15 is a partially fragmentary view showing the sensor of FIGS. 12 and 13 disposed on the skin of a human forearm;

FIG. 15A is a partially fragmentary view showing the sensor of FIGS. 12 and 13 disposed on the skin of a human upper arm (bicep); and

FIG. 16 is a graph showing the response of the sensor when a subject's elbow is flexed.

### DETAILED DESCRIPTION

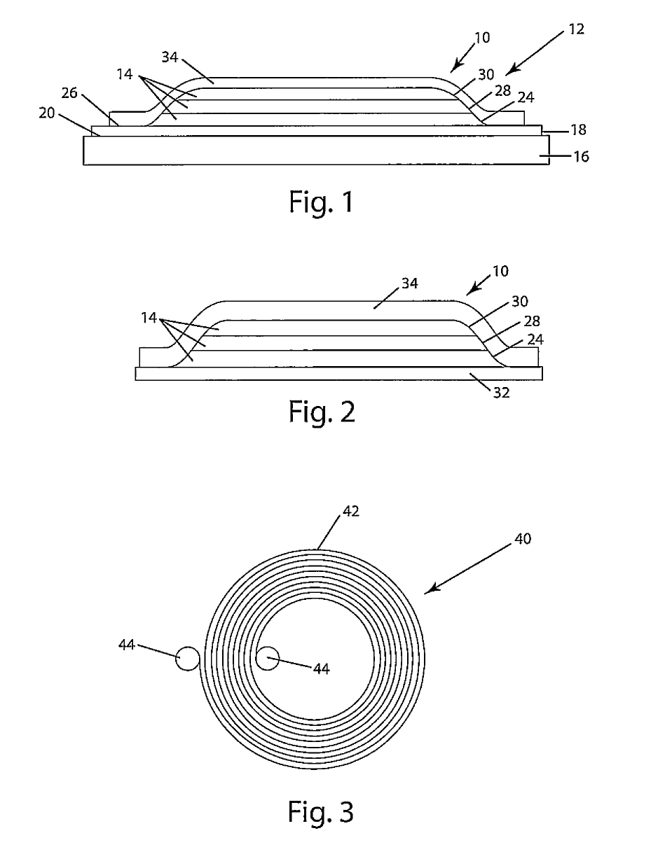

For purposes of description herein the terms “upper,” “lower,” “right,” “left,” “rear,” “front,” “vertical,” “horizontal,” and derivatives thereof shall relate to the assembly as oriented in FIG. 1. However, it is to be understood that the device may assume various alternative orientations and step sequences, except where expressly specified to the contrary. It is also to be understood that the specific devices and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

FIGS. 1 and 2 depict one embodiment of a self-supported electronic device 10 and an assembly 12 for forming the self-supported electronic device 10. Self-supported electronic device 10, as described herein, is a thin film electronic device wherein at least a portion of the electronic device is not supported by a material carrier. Generally, thin film electronic devices as used herein include printed electronic devices, or other similarly produced electronic devices having at least one device layer 14, each device layer 14 contributing to a functional electronic device 10, with each device layer 14 preferably ranging in thickness from 10 nanometers to 60 nanometers. Examples of electronic devices that can be produced as self-supported electronic devices 10 herein include without limitation, an inductance coil, an antenna, an RFID antenna, a heavy metal ion sensor, a capacitor, a supercapacitor, a pressure sensor, a thin film transistor, a resistor, a diode, an organic light emitting diode, an accelerometer, or any other electronic device that is unsupported by a material carrier. Self-supported electronic devices 10 can also include a combination of electric devices that form a functional circuit. As used herein, the term self-supported electronic device 10 also includes electronic devices such as cantilever sensors which are only partially unsupported by a material carrier, as described in greater detail below.

As shown in the embodiment of the assembly 12 shown FIG. 1, the assembly 12 (produced during manufacturing of the self-supported electronic device 10) includes a substrate 16 with a sacrificial layer 18 disposed on a top surface 20 of the substrate 16. The sacrificial layer 18 is soluble in a chosen solvent. A first device layer 24 is disposed on a top surface 26 the sacrificial layer 18, and a second device layer 28 and third device layer 30 are disposed over the first device layer 24 to form the self-supported electronic device 10. In alternate embodiments, the self-supported electronic device 10 includes only one device layer 14, or includes a plurality of device layers 14 as useful to carry out a desired electrical function. To remove the self-supported electronic device 10 from the substrate 16, the chosen solvent is used to at least partially dissolve the sacrificial layer 18, resulting in the separation from the substrate 16 of the self-supported electronic device 10, which optionally incorporates a portion of the sacrificial layer 18, one embodiment of which is illustrated in FIG. 2.

Generally, the substrate 16 used in production of the self-supported electronic device 10, as shown in the embodiment depicted in FIG. 1, can be chosen from any material suitable for the processing steps to form the self-supported electronic device 10 thereon, wherein the material of the substrate 16 is also is compatible with at least the sacrificial layer 18 which is applied thereto. Substrates 16 can be rigid or flexible, and optionally include rigid or flexible traditional electronic device substrates, such as PET, PEN, glass, polyimide, polycarbonate, Mylar, polyethylene, aluminum, stainless steel, or silicon wafer. Alternative substrates 16 can also be used in the methods disclosed herein, because the substrates 16 are not directly in contact with the self-supporting electronic device 10, and because the substrates 16 are removed before use of the self-supported electronic devices 10, and optionally before final processing steps for producing the self-supported electronic device 10 or positioning the device 10 in its final position for use. Therefore, substrates 16 that would otherwise be unsuitable for use in an electronic device can be used as long as they are compatible with the sacrificial layer 18 and the processing steps of forming the self-supported electronic device 10.

The sacrificial layer 18, which is disposed on the top surface 20 of the substrate 16, serves to separate the substrate 16 from the self-supported electronic device 10, and allows removal of the self-supported electronic device 10 from the top surface 20 of the substrate 16. The sacrificial layer 18 is a material, which is substantially soluble in the chosen solvent, and which is preferably substantially insoluble in the first device layer 24, or any device layer 14 that will come into direct contact with the sacrificial layer 18. In one preferred embodiment, the sacrificial layer 18 is a water-soluble polymer. Examples of such polymers are sodium alginate, hydroxyethylated cellulose, carboxymethylated cellulose, guar gum, carboxymethylated starch, ethylated starch, polyvinyl alcohol, plant and animal proteins, gum arabic, carrageenan gum, hydroxypropylcellulose, hydroxypropylmethyl cellulose, and methylcellulose. The water-soluble polymer is preferably applied to the top surface 20 of the substrate 16 as a film to form the sacrificial layer 18. In another preferred embodiment, the water-soluble polymer includes a hydrocolloid, protein, polysaccharides or derivatives of the foregoing. Alternatively, solvent soluble polymers can be used as the sacrificial layer 18, including without limitation, ethylcellulose, polylactic acids, and polyhydroxyalkaonates.

The composition of the sacrificial layer 18 determines the appropriate solvent to use in any given embodiment of the method for preparing the self-supporting electronic devices 10 disclosed herein. For example, where a water-soluble polymer is used for the sacrificial layer 18, water is one appropriate solvent to be used to solubilize the solvent. When using ethylcellulose as the sacrificial layer 18, the solvent chosen to solubilize the ethylcellulose is preferably a mixture of aromatic hydrocarbons and lower molecular weight aliphatic alcohols such as toluene, xylene or ethylbenzene with ethanol, methanol, isopropanol or n-butanol. Polylactic acids are preferably used in conjunction with chlorinated solvents, hot benzene, tetrahydrofuran or dioxane as the solvent. Polyhydroxyalkaonates are preferably used in conjunction with halogenated solvents such as chloroform, dichloromethane, or dichloroethane.

In certain preferred embodiments, a plasticizer is added to the sacrificial layer 18, to improve characteristics of the sacrificial layer 18 such as increasing elasticity, flexibility, and toughness; reducing brittleness; and preventing cracking. Low molecular weight, non-volatile plasticizers are preferred for addition to sacrificial layers 18 which are made of polysaccharide films, including, without limitation, propylene glycol, glycerol, sorbitol, and glycerin. These plasticizers create a greater distance between polar groups within the polysaccharide molecules of the sacrificial layer 18, which reduces the attraction between adjacent polymeric chains. The preferred amount of plasticizer added into hydrocolloid solutions used for the sacrificial layer 18 can vary between about 10% and 60% by weight of the hydrocolloid. Water can also be used as a plasticizer in the sacrificial layer 18, and therefore the moisture content or relative humidity of the environment will potentially affect the properties of the sacrificial layer 18. Addition of plasticizers to the sacrificial layer 18 also decreases the ability of the sacrificial layer 18 to attract water, and slows the time to solubilize the sacrificial layer 18 if water is used as the solvent, and may also decrease the tensile strength and increase the tackiness of the sacrificial layer 18.

In certain embodiments, the sacrificial layer 18 is not completely solubilized in the solvent. In some embodiments, it is preferable to completely remove the sacrificial layer 18 from the self-supported electronic device 10. In other embodiments, it is preferable to only partially remove the sacrificial layer 18 from the self-supported electronic device 10. In embodiments where the sacrificial layer 18 is not entirely removed, the sacrificial layer 18 is preferably solubilized enough to separate the self-supported electronic device 10 from the top surface 20 of the substrate 16, with a residue or portion 32 of the sacrificial layer 18 remaining on the self-supported electronic device 10. Where a portion 32 of the sacrificial layer 18 remains on the self-supported electronic device 10, the portion 32 is optionally used as an adhesive to secure the self-supported electronic device 10 in its final desired location. For example, the portion 32 of the sacrificial layer 18 remaining on the self-supported electronic device 10 can be used as an adhesive to secure the self-supported electronic device 10 to skin where the self-supported electronic device 10 is desired for use in an application where it is applied to a subject's skin. In alternate embodiments, a separate adhesive can be applied to the self-supported electronic device 10 to secure the self-supported electronic device 10 in its desired location of use.

The self-supporting electronic device 10 includes one or more functional materials which are applied in one or more device layers 14. The functional materials of the device layers 14 are preferably formulated as inks which are printed onto the sacrificial layer 18 (or onto one of the previously applied device layers 14). Printing is a preferred method of application of the device layers 14 because printing is an additive process, which allows the functional materials to be applied in the specific design intended, minimizing the amount of material that must be used and the number of processing steps in manufacturing. The inks used, and their functional materials, are preferably substantially insoluble in the solvent that will be used to dissolve the sacrificial layer 18. In one preferred embodiment, all of the device layers 14 are insoluble in the solvent to be used. In another preferred embodiment, at least an outer device layer 14 is insoluble in the solvent and will protect the device layers 14 underneath the outer device layer 14 from dissolving in the solvent. Preferably, any device layers 14 that are soluble in the solvent are encapsulated with other device layers 14 that are substantially insoluble in the solvent.

The self-supported electronic devices 10 preferably include one or more device layers 14 which have predetermined electrical properties to perform as the desired electronic device. For example, the first device layer 24 in the embodiment depicted in FIGS. 1 and 2 can be a conductive layer and the second device layer 28 can be a dielectric layer, with a conductive ink used to print the first device layer 24 and a dielectric ink used to print the second device layer 28. Alternatively, the first device layer 24 can be a dielectric layer, to electronically insulate the self-supported electronic device 10 from any underlying surface to which the self-supported electronic device 10 may ultimately be affixed, allowing the self-supported electronic device 10 to function properly when affixed to a range of different materials. In yet another embodiment, the first device layer 24 is optionally a barrier layer, such that the first device layer 24 is a material in which the sacrificial layer 18 is substantially insoluble. This allows for the printing of subsequent device layers 14 in the self-supported electronic device 10 that may otherwise solubilize the sacrificial layer 18. Some embodiments of self-supported electronic devices 10 as described herein are flexible enough to be rolled or bent, allowing the creation of electronic devices with enhanced features, such as rolled supercapacitors, as described in greater detail below.

The ink chosen for printing the device layers 14 of the self-supported electronic device 10 will depend at least partially on the composition of the sacrificial layer 18. The sacrificial layer 18 is preferably substantially insoluble in the inks used in the device layers 14. Additionally, the inks used in the device layers 14 are preferably film-forming when applied over the sacrificial layer 18. Solvent-based, water-based, and UV-curable inks can be used for printing the device layers 14 on the sacrificial layer 18, including without limitation, semiconductors, resistive, and emissive polymer inks, which can be applied to the sacrificial layer 18 using various printing methods such as screen printing, inkjet printing, flexographic printing, gravure printing, offset gravure printing, rotogravure printing, offset rotogravure printing, offset lithography, or other printing processes that are suitable for use with the solvent-based, water-based, or UV-curable inks used for the device layers 14. Additionally, each device layer 14 can be applied to the self-supported electronic device 10 independently, allowing the use of different printing methods for different device layers 14. Each device layer 14 preferably has a thickness from about 0.1 μm to about 60 μm, depending on the printing method used and the viscosity of the ink. The viscosity of the ink used for printing the device layers 14 preferably varies depending on the printing method to be used. For screen printing, the ink preferably has a viscosity of between 1,000 centipoise (cP) and 10,000 cP. For rotogravure or offset rotogravure, the viscosity of the ink is preferably between 50 cP and 1,000 cP. For flexographic printing, the viscosity of the ink is preferably between 100 cP and 5,000 cP, and for offset lithography, the viscosity of the ink is preferably between 1,000 cP and 50,000 cP. For inkjet printing, the viscosity of the ink is preferably between 5 cP and 100 cP, and for aerosol jet printing the viscosity of the ink is preferably between 1 cP and 1000 cP. For microplotter printing the viscosity of the ink is preferably between 1 cP and 450 cP.

Non-limiting examples of suitable conductive inks for use in the device layers 14 include, without limitation, flake silver inks, nano silver inks, flake copper inks, nano copper inks, inks containing carbon nanotubes, carbon inks, gold inks, graphene inks, and nickel inks. Several non-limiting examples of presently available UV-curable conductive inks suitable for screen printing device layers 14 include, without limitation, UHF™ ink available from Polychem, and ELECTRODAG PD-054™ ink available from Henkel and AST 6200™ solvent-based flake silver ink, available from Sun Chemical Co. Several non-limiting examples of presently available UV-curable dielectric inks suitable for screen printing the device layers 14 include, without limitation, UV-1006S™ available from Conductive Compounds, UV2530™ available from Conductive Compounds, UV2S60™ available from Conductive Compounds, UV-2531™ available from Conductive Compounds, EDAG 1020A™ available from Henkel; EDAG 452SS™ available from Henkel, and EDAG PF455B™ available from Henkel. Other inks having appropriate functional properties for the device layers 14 can be used.

Direct printing of the device layer 14 on the sacrificial layer 18 can achieve resolutions as low as 10 microns if the properties of the ink used for the device layer 14, such as viscosity and wetting properties, are matched to the surface energy of the sacrificial layer 18. In some preferred embodiments, the device layers 14 include ink printed over a large area, and in others fine resolution of printed device layers 14 are desirable.

In traditional electronic devices, the properties of the substrate 16, such as the temperature resistance, solvent compatibility, smoothness, cost, surface energy, thickness, rigidity, and functional properties, can limit the functional materials used in the creation of the traditional electronic device and the printing methods or other formation methods available. In contrast, with self-supported electronic devices 10, the self-supported electronic device 10 will be removed from the substrate 16, and is separated therefrom by the sacrificial layer 18. Therefore, the substrate 16 can be selected based in its mechanical properties to allow the use of desired functional materials in the production of the self-supported electronic devices 10, even if the substrate 16 would not be suitable for the desired end use of the self-supported electronic device 10 or for all processing steps of the formation of the self-supported electronic device 10. For example, in a flexible electronic device, where the electronic device is not removed from the substrate 16, the substrate 16 chosen must have sufficient flexibility for the desired end use of the electronic device. However, flexible substrates tend to have limited temperature processing ranges, requiring the balancing of flexibility with the desired temperature processing parameters of the functional materials being applied to form the electronic device. According to the present disclosure, where the self-supported electronic device 10 is removable from the substrate 16, the substrate 16 chosen can be a rigid substrate 16 that is capable of handling high temperature processing as desired for the preferred functional materials. In this case, the processing temperatures achievable would still be bounded by the degradation temperatures of the sacrificial layer 18 and the self-supported electronic device 10. Additionally, substrates 16 are preferably re-usable in the formation of the self-supported electronic devices 10, allowing for the use of substrates 16 that would otherwise be cost prohibitive.

An encapsulating layer 34 is optionally deposited over the device layers 14 to seal the self-supported electronic device 10. The encapsulating layer 34 is optionally applied prior to solubilizing the sacrificial layer 18, after removing the self-supported electronic device 10 from the underlying substrate 16, or after applying the self-supported electronic device 10 to its final use position. The encapsulating layer 34 is preferably a film-forming layer that creates a barrier when applied to the self-supported electronic device 10. In one preferred embodiment, the encapsulating layer 34 is a silicone-based material that desirably imparts water-resistant properties to the self-supported electronic device 10. If the encapsulating layer 34 is applied prior to solubilizing the sacrificial layer 18, it is preferable to coat a smaller surface area with the encapsulating layer 34 than the area covered by the sacrificial layer 18. This allows a wicking action to solubilize the sacrificial layer 18 to release the self-supported electronic device 10 from the substrate 16. If the encapsulating layer 34 is applied after removing the self-supported electronic device 10 from the underlying substrate 16 or after applying the self-supported electronic device 10 to its final use position, then the encapsulating layer 34 preferably has a surface area equal to or larger than the area of the self-supported electronic device 10 to better seal the self-supported electronic device 10. In another preferred embodiment, the encapsulating layer 34 can be a passivation layer, such as a silicone spray, to protect the device layers 14 from corrosive effects.

In certain embodiments of the self-supported electronic device 10 described herein, the sacrificial layer 18 or the substrate 16 can be used to add three-dimensional shape to the self-supported electronic device 10, or to allow a portion of the self-supported electronic device 10 to be released from the substrate 16.

Generally, a method of manufacturing self-supporting electronic devices 10 as described herein includes the steps of applying the sacrificial layer 18 to the top surface 20 of the substrate 16, and applying at least one device layer 14 over the sacrificial layer 18 in a predetermined pattern to form the self-supporting electronic device 10. The chosen solvent, in which the sacrificial layer 18 is soluble, is then contacted with the sacrificial layer 18, to at least partially dissolve the sacrificial layer 18 and allow separation of the self-supported electronic device 10 from the substrate 16. In an alternate embodiment, the sacrificial layer 18 and the self-supported electronic device 10 can be peeled or otherwise separated from the substrate 16 for storage, and dissolution of the sacrificial layer 18 is carried out at a later time (e.g., at the time of application of the self-supporting electronic device 10 to its use position).

The sacrificial layer 18 can be applied to the substrate 16 using a variety of methods, including without limitation casting, curtain coating, spraying or printing the sacrificial layer 18 onto the top surface 20 of the substrate 16. In some embodiments, the sacrificial layer 18 is dried or cured after application to the top surface 20 of the substrate 16.

The device layer 14 or layers 14 can also be applied to the sacrificial layer 18 using a variety of methods, though the least one device layer 14 is preferably printed on the sacrificial layer 18 in the predetermined pattern to form the desired self-supported electronic device 10. Where multiple device layers 14 are incorporated, the different layers 14 optionally include functional materials with different properties, allowing the creation of various types of self-supported electronic devices 10, several examples of which are discussed in greater detail below. Each device layer 14 is optionally dried or cured after its application.

Following formation of the self-supported electronic device 10 on the sacrificial layer 18 and the substrate 16, the solvent is applied to dissolve the sacrificial layer 18. In some embodiments it may be preferable to submerge the substrate 16 with the self-supported electronic device 10 thereon in the solvent. In other embodiments, the solvent may be sprayed, coated, painted or otherwise applied to the sacrificial layer 18 to dissolve the sacrificial layer 18. In some preferred embodiments, the sacrificial layer 18 is only partially removed, with the dissolution sufficient to release the self-supported electronic device 10 from the substrate 16. When the self-supported electronic device 10 is not placed immediately in its position of use following removal from the substrate 16, the self-supported electronic device 10 can be placed on a silicone release sheet or other non-stick sheet until the desired time of use.

One embodiment of a self-supported electronic device 10, as illustrated in FIG. 3, is a self-supported inductance coil 40. The self-supported inductance coil 40 includes at least one continuous spiral device layer 42, with a terminal 44 at each end thereof. The inductance coil 40 is formed by coating the sacrificial layer 18 on the substrate 16, and printing the spiral device layer 42 using conductive ink. The sacrificial layer 18 is then dissolved in the solvent to remove the inductance coil 40 from the substrate 16.

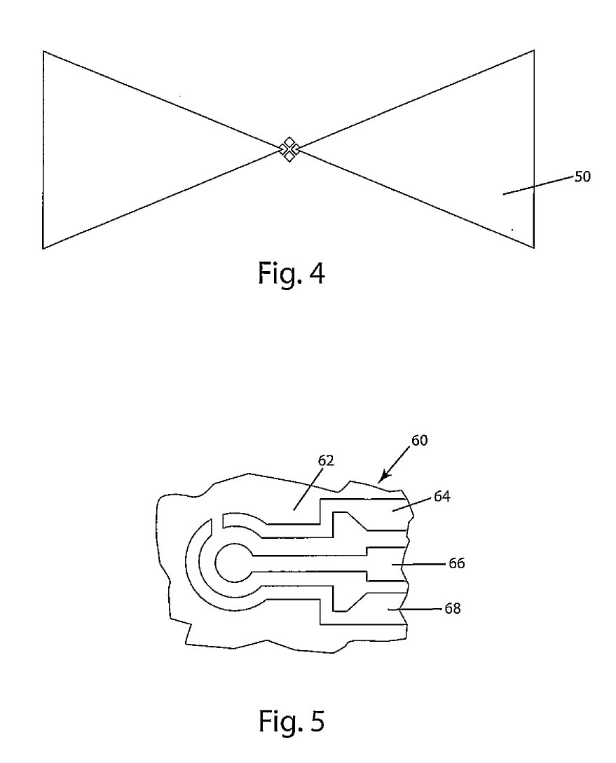

Another embodiment of a self-supported electronic device 10 is illustrated in FIG. 4. The self-supported electronic device 10 illustrated in FIG. 4 is an RFID antenna 50. Similarly to the inductance coil 40, the RFID antenna 50 is formed by coating the sacrificial layer 18 on the substrate 16, and printing the RFID antenna 50 on sacrificial layer 18 using conductive ink. The sacrificial layer 18 is then dissolved in the solvent to remove the RFID antenna 50 from the substrate 16. RFID antenna 50 may include one or more layers of flexible or rigid polymer material (not shown) or other suitable material formed on sacrificial layer 18 and/or above the conductive layer forming antenna 50 to structurally support the conductive layer that forms antenna 50.

Another embodiment of a self-supported electronic device 10 is illustrated in FIG. 5, as a heavy metal ion sensor 60. The embodiment of the heavy metal ion sensor 60 shown in FIG. 5 is formed by coating the sacrificial layer 18 on the substrate 16 and then printing a first rectangular dielectric ink layer 62. Conductive counter electrodes 64 and 68 are printed, as are two conductive layers of a working electrode 66. The sacrificial layer 18 is then dissolved in the solvent to remove the heavy metal ion sensor 60 from the substrate 16.

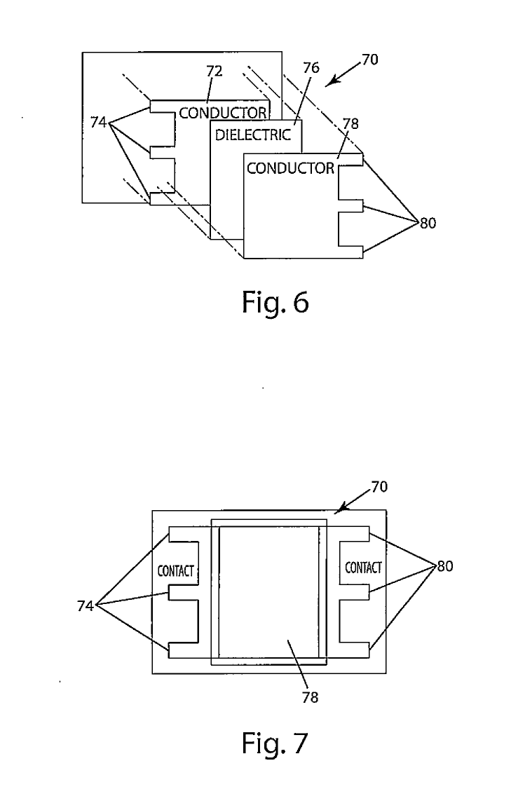

Another embodiment of a self-supported electronic device 10 is illustrated in FIGS. 6 and 7, as a capacitor 70. The embodiment of the capacitor 70 shown in FIGS. 6 and 7 is formed by coating the sacrificial layer 18 on the substrate 16, and then printing a first device layer 72 in generally rectangular form with contacts 74 using conductive ink. A second device layer 76 is printed in rectangular form using a dielectric ink overlapping the first device layer 72. The third device layer 78 is printed in generally rectangular form with contacts 80 using conductive ink, overlapping the first and second device layers 72, 76, to form two conductive layers 72, 78 separated by a dielectric layer 76. The sacrificial layer 18 is then dissolved in the solvent to remove the capacitor 70 from the substrate 16.

In one specific example, a self-supporting electronic device 10, which functions as a capacitor 70, was formed using the substrate 16 of Melinex ST 506 PET, available from DuPont. The sacrificial layer 18 was formed by adding dried alginate into a pre-weighed amount of distilled water under agitation to obtain a 6% aqueous solution of alginate. The alginate solution was allowed to mix for 20 minutes. 25% glycerol by weight of alginate was added and the alginate solution was allowed to further mix for 40 minutes to hydrate the alginate. The glycerol was added as a plasticizer to improve the flexibility of the sacrificial layer 18 formed from the alginate solution and prevent cracking of the sacrificial layer 18 upon drying. The alginate solution was then placed in a closed container and held overnight to degas. The alginate solution was then applied by pipette to the substrate 16, which was cleaned with isopropyl alcohol just prior to application of the alginate solution. Drawdowns were performed by use of Meyer rods or Byrd applicators to coat the alginate solution on the substrate 16. The substrate 16 with the coated alginate solution was placed in a TAPPI standard test room at drying conditions of 50% relative humidity and 23° C. to form the sacrificial layer 18 on the substrate 16.

The first device layer 72, comprising a conductive solvent-based silver flake ink, AST 6200 from Sun Chemical, was screen printed over the sacrificial layer 18 using an AMI MSP-485 semi-automated screen printer and a 230 LPI mesh 0.0011″ wire diameter at 45° wire angle screen and an emulsion layer of 10 μm thickness produced by Microscreen of South Bend, Ind. The conductive solvent-based ink of first device layer 72 was thermally dried at 135 F for 5 minutes until fully dried (no significant change in resistivity with time). After drying the conductive ink to form the first device layer 72, the second device layer 76 was printed using a UV dielectric ink, Electrodag PF-455B from Henkel, and the same screen printer and the same type of screen as used for the conductive ink. The dielectric ink second device layer 76 was cured using a Fusion UV drier equipped with a D60 bulb by passing the substrate 16 with the sacrificial layer 18, first device layer 72 and second device layer 79 through the drier 3 to 4 times until completely cured (no longer tacky to the touch). The third device layer 78 was printed over the second device layer 76, the third device layer 78 including another layer of the conductive solvent based silver flake ink. The third device layer 78 was also thermally dried. The resulting self-supported capacitor 70 includes three layers, the conductive first layer 72, the dielectric second layer 76, and the conductive third layer 78. The self-supported capacitor 70 is removed from the substrate 16 by applying water to the assembly 12, thereby dissolving the sacrificial layer 18 and separating the capacitor 70 from the substrate 16.

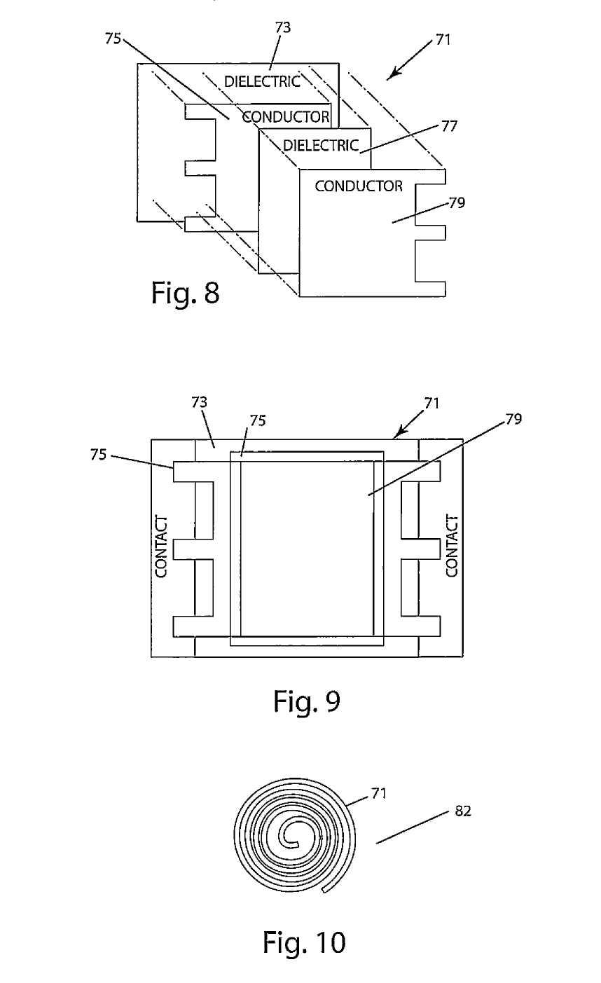

One variation of the capacitor 70 illustrated in FIGS. 6 and 7 is a supercapacitor 82, one embodiment of which is illustrated in FIGS. 8-10. The embodiment of the super capacitor 82 as disclosed herein is formed by rolling a 4 layer capacitor 71 with a first device layer 73 comprising a dielectric material, a second device layer 75 comprising a conductive material, a third device layer 77 comprising a dielectric material, and a fourth device layer 79 comprising a conductive material. To form the 4-layer capacitor 71, the sacrificial layer 18 is printed on a substrate 16, and then the first device layer 73 is printed using dielectric ink. The second device layer 75 is printed over the first device layer 73 using conductive ink after the first device layer 73 is cured. The second device layer 75 is then cured, and the third device layer 77 is printed over the second device layer 75 using dielectric ink and cured. To complete the 4-layer capacitor 71, the fourth device layer 79 is printed using conductive ink over the third device layer 77, and is cured. The flexibility of the capacitor 71 allows the capacitor 71 to be rolled to form the super capacitor 82, as shown in FIG. 10.

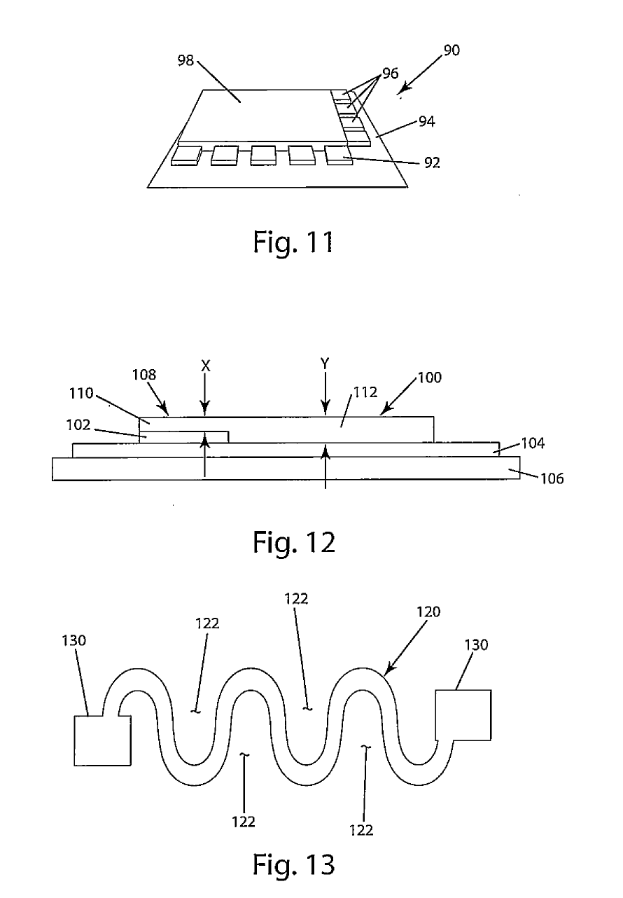

Another variation of the capacitor 70 illustrated in FIGS. 6 and 7 is a capacitive pressure sensor 90, one embodiment of which is illustrated in FIG. 11 The capacitive pressure sensor 90 as shown in FIG. 11 is formed by coating a sacrificial layer 18 on a substrate 16, and then printing a first device layer 92 of bars using conductive ink. A second device layer 94 of dielectric ink is printed over the first layer 92 of conductive ink. A third device layer 96 of conductive ink is printed, having bars positioned generally perpendicularly from the bars of the first device layer 92. A fourth device layer 98 is printed over the remaining device layers 92, 94, 96, using a passivation material.

Yet another self-supported electronic device 10 is a cantilevered sensor 100, one embodiment of which is shown in FIG. 12. The embodiment of the cantilevered sensor 100 is formed by applying a shaping sacrificial layer 102 under the cantilevered sensor 100. The shaping sacrificial layer 102 is optionally applied over a full sacrificial layer 104. In other embodiments, the shaping sacrificial layer 102 is applied directly to the substrate 106. A first device layer 108 of conductive ink is then printed or otherwise applied over the shaping sacrificial layer 102, resulting in a first device layer 108 with at least two portions, with a first or beam portion 110 having a first thickness x over the shaping sacrificial layer 102, and a second or base portion 112 having a second thickness y where the shaping sacrificial layer 102 is not present. After forming the cantilever sensor 100 on the substrate 106 over the shaping sacrificial layer 102, a solvent is applied to solubilize the shaping sacrificial layer 102, leaving a void beneath the first portion 110 of the cantilever sensor 100. In one preferred embodiment, the shaping sacrificial layer 102 is 1 micron thick, and is 1″ wide. The conductive first device layer 108 printed over the shaping sacrificial layer 102 is 4″ wide, with a first portion 110 that is 1 micron thick and a second portion 112 that is 2 microns thick.

Another aspect of the present invention is a stretchable printed strain sensor 120 (FIG. 13). Stretchable printed strain sensor 120 has a wavy form including a plurality of oppositely-oriented U-shaped portions 122 that are joined together to form a plurality of S-shaped bends. The S-shaped bends of sensor 120 may be sinusoidal in shape, or other suitable shape. Enlarged rectangular ends 130 of the sensor 120 form electrodes that may be utilized to electrically connect the sensor to other electronic devices. As discussed in more detail below, strain sensor 120 may be fabricated by screen printing Carbon nano-tubes (CNTs) ink onto a water-soluble sacrificial substrate. The printed sensor, along with the sacrificial layer, may be transferred onto the skin of a human (e.g. an arm). Water may then be used to dissolve the sacrificial layer, leaving the sensor 120 disposed/adhered to the skin. The capability of printed sensor 120 for tracking the movement of the human body was demonstrated by subjecting the sensor 120 to extension and flexion of an arm.

### EXAMPLE

A. Chemicals, and Sample Preparation

Polyvinyl Alcohol (PVA) substrate (Watson QSA 2000) was used as a sacrificial layer for printing and transferring the sensor directly onto the skin of a human subject. CNT ink (VC101 from SWENT) was used for the fabrication of a resistive wavy form strain sensor 120 that may include a plurality of S-bends and enlarged end portions/electrodes 130 (FIG. 13). An silver ink (Electrodag 479SS) from Henkel was used for printing of interconnects in the wavy form on the Thermoplastic polyurethane (TPU) from Bemis Associates, Inc. Conductive silver epoxy from CircuitWorks® (CW-2400) was used for attaching the interconnects to the sensor 120.

B. Sensor Fabrication

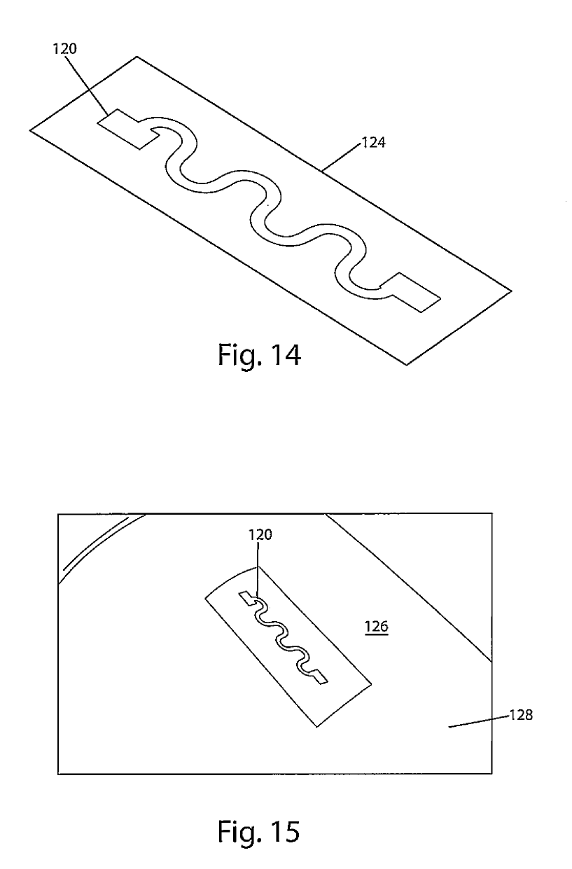

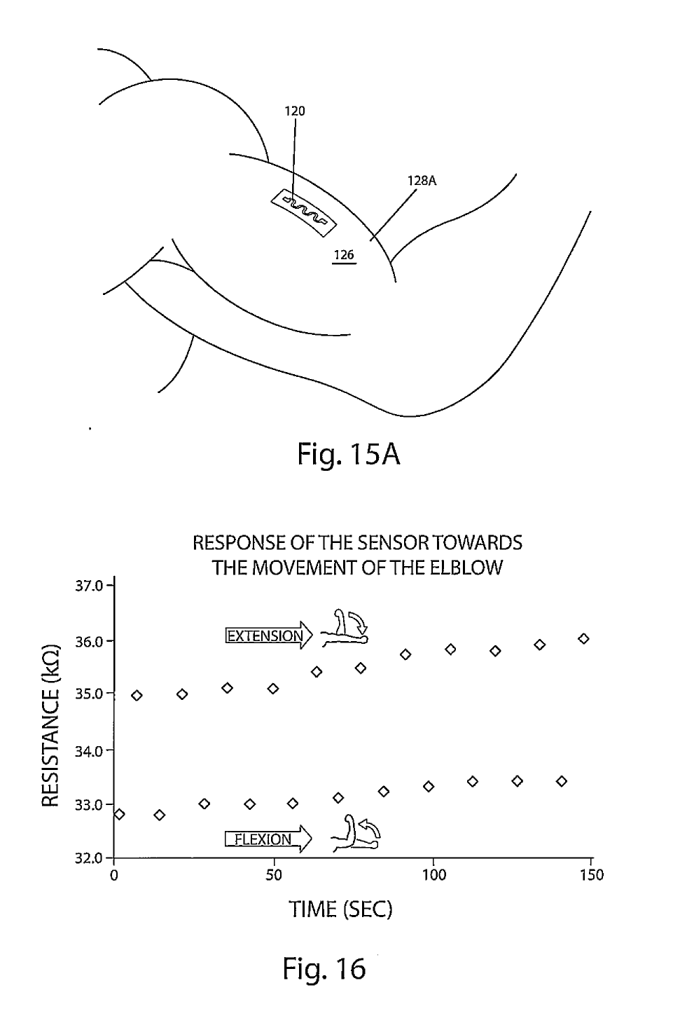

Sensor 120 (FIG. 13) has a wavy shape with a 800 μm line width and overall dimensions of 3.0 cm×0.4 cm. Sensor 120 was screen printed using CNT ink (SWeNT CV100) on a sacrificial water-soluble polymer based PVA substrate (Watson QSA 2000). Printed sensor 120 on sacrificial substrate 124 is shown in FIG. 14. A semiautomatic screen printing press (AMI 485) was used for deposition of CNTS and Isopropyl alcohol was used for cleaning of the screen. The CNT ink was cured in a VWR oven at 100° C. for 10 minutes. In the next step, in order to transfer sensor 120 onto a human body, the skin 126 of a human forearm 128 (FIG. 15) was wetted and the printed sensor was then mounted on the left forearm 128. The sacrificial PVA layer was then washed away using water, thereby completing the transfer of sensor 120 onto the skin 126. The sensor 120 after placement on skin 126 of a human forearm 128 is shown in FIG. 15. Sensor 120 may also be positioned on skin 126 of other body parts (e.g. upper arm/bicep) as shown in FIG. 15A. A Bruker Contour GTL EN 61010 profilometer was used to study the thickness of the deposited CNTs. The average thickness of the printed CNT layer was measured as 5.6 μm.

C. Experimental Procedure

Interconnects (not shown) were attached to the electrodes 130 of sensor 120 prior to mounting on the skin 126 utilizing conductive silver epoxy. The interconnects were connected to an Agilent E4980A precision LCR meter (not shown) for measuring/recording the resistive response of the strain sensor 120 during flexion and extension of the forearm 128. The change in the resistance of the sensor 120 was recorded after each time movement of the elbow.

### RESULTS AND DISCUSSION

The response of the printed wearable sensor 120, after placing on the arm, is shown in FIG. 16. The sensor 120 was subjected to both flexion and extension movement of the arm, thereby resulting in a change of resistance of the sensor 120. It was observed that the average resistance of the sensor 120 increased from 32.8 kΩ to 36 kΩ for multiple flexion and extension movements of the elbow, which corresponds to a 10% change in the sensor response. In addition, a 2% change in the base resistance of the sensor 120 was observed, when the elbow was brought back to the original position after 10 cycles.

In order to reduce potential breakage of sensor 120, the thickness of the conductive layer of sensor 120 may be increased to 20 microns, 30 microns, 40 microns, or more. Multiple layers of conductive and/or non-conductive materials may also be utilized to provide increased strength and reduce breakage of sensor 120.

The sensor 120 may also be encapsulated using spin coated poly-imide or Silicone based materials such as Polydimethylsiloxane (PDMS) to strengthen sensor 120 and reduce breakage of the structure after mounting on a human body.

It is also important to note that the construction and arrangement of the elements of the device as shown in the exemplary embodiments is illustrative only. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements shown as multiple parts may be integrally formed, the operation of the interfaces may be reversed or otherwise varied, the length or width of the structures and/or members or connector or other elements of the system may be varied, the nature or number of adjustment positions provided between the elements may be varied. It should be noted that the elements and/or assemblies of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

It will be understood that any described processes or steps within described processes may be combined with other disclosed processes or steps to form structures within the scope of the present device. The exemplary structures and processes disclosed herein are for illustrative purposes and are not to be construed as limiting.

It is also to be understood that variations and modifications can be made on the aforementioned structures and methods without departing from the concepts of the present device, and further it is to be understood that such concepts are intended to be covered by the following claims unless these claims by their language expressly state otherwise.

The above description is considered that of the illustrated embodiments only. Modifications of the device will occur to those skilled in the art and to those who make or use the device. Therefore, it is understood that the embodiments shown in the drawings and described above is merely for illustrative purposes and not intended to limit the scope of the device, which is defined by the following claims as interpreted according to the principles of patent law, including the Doctrine of Equivalents.

1. A method of forming a self-supported electronic device, comprising:
depositing a sacrificial layer on a first surface substrate, wherein the sacrificial layer is substantially soluble in a first solvent;
depositing at least one device layer in a desired pattern on the sacrificial layer, wherein the at least one device layer is not substantially soluble in the first solvent and wherein the sacrificial layer is substantially insoluble in the at least one device layer; and
at least partially dissolving the sacrificial layer in the first solvent to release at least a portion of the first device layer from the substrate.

2. The method of claim 1, wherein:
the first solvent comprises water.

3. The method of claim 2, wherein:
the sacrificial layer comprises a water-soluble polymer.

4. The method of claim 3, wherein:
the sacrificial layer comprises a polysaccharide film.

5. The method of claim 4, wherein:
the sacrificial layer comprises a plasticizer.

6. The method of claim 5, wherein:
the plasticizer comprises about 10% to about 60% by weight of the sacrificial layer.

7. The method of claim 1, wherein:
the sacrificial layer is completely dissolved and removed from the substrate.

8. The method of claim 1, wherein:
the device layer comprises an electrically conductive material.

9. The method of claim 8, wherein:
the device layer comprises a stretchable strain sensor having at least one S-shaped bend.

10. The method of claim 9, including:
positioning the device layer and sacrificial layer on a subject's skin prior to at least partially dissolving the sacrificial layer.

11. The method of claim 10, wherein:
the device layer comprises carbon nanotubes that are deposited on the sacrificial layer.

12. The method of claim 1, wherein:
the at least one device layer comprises a conductive layer and a dielectric layer.

13. The method of claim 12, wherein:
the self-supported electronic device comprises a heavy metal ion sensor;
the dielectric layer is deposited on the sacrificial layer;
the conductive layer is printed on the dielectric layer to form a counter electrode and at least two working electrodes that are spaced apart from the counter electrode.

14. The method of claim 1, including:
depositing an encapsulating layer over the at least one device layer.

15. The method of claim 14, wherein:
the encapsulating layer is deposited over the at least one device layer prior to at least partially dissolving the sacrificial layer.

16. The method of claim 14, wherein:
the encapsulating layer is deposited over the at least one device layer after at least partially dissolving the sacrificial layer, and wherein the encapsulating layer has a surface area equal to or larger than a surface area of the at least one device layer.

17. The method of claim 1, wherein:
the at least one device layer comprises conductive material deposited in a continuous spiral that is removed from the first surface substrate to form an inductance coil.

18. The method of claim 1, wherein:
the at least one device layer comprises conductive material defining first and second triangular regions, each triangular region defining a first corner, and wherein the first corners are disposed directly adjacent one another to define an RFID antenna.

19. The method of 1, wherein:
the at least one device layer comprises a plurality of device layers including at least a first conductive layer that is deposited on the sacrificial layer, a dielectric layer that is deposited on the first conductive layer, and a second conductive layer that is deposited on the dielectric layer to form a capacitor.

20. The method of claim 19, including:
rolling the device layers to form a capacitor that is generally cylindrical in form.

21. The method of claim 1, wherein:
the at least one device layer comprises a first layer including a plurality of spaced apart parallel bars of conductive material, a second layer of dielectric material covering at least a central portion of the bars, and a third layer comprising a plurality of spaced apart parallel bars of conductive material disposed on the layer of dielectric material, wherein the parallel bars of the third layer are generally perpendicular to the bars of the first layer.

22. The method of claim 1, wherein:
the sacrificial layer comprises a shaping sacrificial layer that only covers a first portion of the first surface substrate whereby a second portion of the first surface substrate is not covered by the shaping sacrificial layer;
the at least one device layer includes a beam portion that is deposited over the shaping sacrificial layer and a base portion that is deposited over the second portion of the surface substrate;
the shaping sacrificial layer is dissolved such that the beam portion has a thickness that is significantly less than a thickness of the base portion whereby the device layer forms a cantilevered sensor.

23. An assembly for producing a self-supported electronic device, comprising:
a substrate;
a sacrificial layer disposed on a top surface of the substrate, the sacrificial layer being soluble in a first solvent;
at least one device layer disposed on a top surface of the sacrificial layer, having a thickness greater than about 10 nm, wherein the device layer is substantially insoluble in the first solvent, and wherein the sacrificial layer is substantially insoluble in the at least one device layer.

24. The assembly of claim 23, wherein:
the at least one device layer comprises an electrically conductive material.

25. The assembly of claim 23, wherein:
the at least one device layer comprises a conductive layer and a dielectric layer.

26. The assembly of claim 23, including:
an encapsulating layer extending over at least a portion of the at least one device layer.

27. The assembly of claim 23, wherein:
the sacrificial layer is water soluble.

28. The assembly of claim 27, wherein;
the sacrificial layer comprises a water soluble polymer.

29. The assembly of claim 23, wherein:
The substrate comprises a rigid material.

30. A self-supported electronic device, comprising:
a thin film electronic device, wherein at least a portion of the electronic device is not supported by a material carrier.

31. The electronic device of claim 30, wherein:
the thin film electronic device comprises at least one dielectric layer and at least one conductive layer.

32. The electronic device of claim 31, wherein:
the thin film electronic device is formed into a roll.
